(19) United States
(12) Patent Application Publication
(10) Pub. No.: US 2012/0153779 A1
(43) Pub. Date: Jun. 21, 2012

(54) ELECTRONIC COMPONENT

(76) Inventors: Keiji Sato, Chiba-shi (JP); Hitoshi Takeuchi, Chiba-shi (JP); Takahiko Nakamura, Chiba-shi (JP); Kiyoshi Aratake, Chiba-shi (JP); Masashi Numata, Chiba-shi (JP)

(21) Appl. No.: 13/308,896

(22) Filed: Dec. 1, 2011

(30) Foreign Application Priority Data
Dec. 17, 2010 (JP) 2010-282244

(51) Int. Cl. H01L 41/053; H05K 5/06

(52) U.S. Cl. 310/344; 174/59

(57) ABSTRACT

An electronic component includes a glass substrate, a lid that is bonded to the glass substrate, an internal electrode, an external electrode, and a through electrode that is disposed in a through hole passing through the glass substrate and electrically connects the internal electrode to the external electrode. A sputtered metal layer is formed on the end face of a core member of the through electrode, which is made of a metal, by sputtering.

### RELATED APPLICATIONS

This application claims priority under 35 U.S.C. §119 to Japanese Patent Application No. 2010-282244 filed on Dec. 17, 2010, the entire content of which is hereby incorporated by reference.

### BACKGROUND OF THE INVENTION

1. Field of the Invention

The present invention relates to an electronic component including a glass package.

2. Description of the Related Art

In the past, there has been known an electronic component where an internal electrode is provided in a package, an external electrode is provided outside the package, and the internal electrode and the external electrode are electrically connected to each other. As one example of such electronic components, a crystal oscillator, which includes a crystal oscillating piece disposed in a package, is known. The crystal oscillator is used as a reference oscillation source of an electronic device or a clock source of a microcomputer.

The crystal oscillator has a configuration where a crystal oscillating piece is sealed in a small surface mount package that is airtightly sealed. Further, in the past, a crystal oscillator, which uses a glass package as a surface mount package, has been proposed.

A glass package is formed by bonding a lid, which is made of glass or metal, to a glass substrate by a bonding material, and a crystal oscillating piece received in the package is electrically connected to an external electrode, which is formed outside the package, by forming a through electrode in a through hole that is formed at a glass substrate.

The through electrode is formed by disposing a metal core member, formed of an Fe—Ni alloy, a kovar (Fe—Ni—Co) alloy, an Fe—Ni—Cr alloy, or a Dumet wire, in the through hole and filling a space between the core member and the through hole, with lead-free low melting-point glass. Here, a low melting-point means a melting point of about 700° C. or less.

The external electrode is formed by plating a sputtered metal layer serving as a foundation with Ni and Sn. Further, since the surface mount package is fixed to a circuit board by solder, the external electrode requires excellent bondability between the solder and itself.

Meanwhile, a glass package has the following problems. That is, the glass package does not have a property for relaxing stress. For this reason, when vibration or impact is applied to the glass package, the glass package is significantly deformed, so that performance is apt to deteriorate and cracks are apt to be generated. There is also a concern that the glass package is significantly deformed and cracks are generated due to the difference in thermal expansion between the circuit board and the glass package. That is, when summarizing the above, the glass package has a problem in terms of durability.

Accordingly, in order to solve the above-mentioned problems, there is known a configuration where a conductive resin is provided on a foundation layer of an external electrode (see JP-A-2010-4216 and JP-A-2010-103479). According to this configuration, since it is possible to relax an impact or vibration by the foundation layer or a foundation structure even when the impact or vibration is applied to a glass package, durability of the glass package is improved. Accordingly, it is possible to reduce the possibility that the performance of the glass package deteriorates or cracks are generated in the glass package.

However, when the conductive resin is provided on the foundation layer of the external electrode for improving the durability of the glass package, there are the following problems.

That is, since an electrical resistance between the conductive resin and a Ni alloy, such as a Fe—Ni alloy, a kovar alloy, or a Fe—Ni—Cr alloy, which is employed for the through electrode, is large, there is a problem in that the electrical characteristics of a crystal oscillator deteriorate. Further, since the lead-free low melting-point glass filled in the through hole is naturally apt to be in an unstable state, the bondability between the conductive resin and the lead-free low melting-point glass is poor. Accordingly, the bonding strength of the external electrode is reduced, so that the electrical characteristics of the crystal oscillator deteriorate. Meanwhile, these problems are generated not only in the above-mentioned crystal oscillator but also in a general electronic component including a glass package.

### SUMMARY OF THE INVENTION

The invention has been made to solve the above-mentioned problems, and an object of the invention is to provide an electronic component including a glass package that has excellent durability and can improve electrical characteristics.

In order to solve the above-mentioned problems, there is provided an electronic component including a substrate that is made of glass, a lid that is bonded to the substrate, an internal electrode that is formed on one surface of the substrate, an external electrode that is formed on the other surface of the substrate, a through electrode that is disposed in a through hole passing through the substrate and electrically connects the internal electrode to the external electrode, and an electronic element that is provided on one side of the substrate and electrically connected to the internal electrode, wherein the through electrode is formed of a core member that is disposed in the through hole and made of a metal, and lead-free low melting-point glass that seals a space between the core member and the through hole, and a sputtered metal layer is formed on the end face of the core member, which faces the external electrode, by sputtering a metal, the external electrode includes a conductive resin layer and a metal electrode layer that covers the outer side of the conductive resin layer, and the sputtered metal layer and the conductive resin layer are bonded to each other, so that the electrical connection among the internal electrode, the core member, and the external electrode is secured.

According to the invention, since the external electrode is provided with the conductive resin layer, it is possible to relax a vibration and impact at the conductive resin layer and to improve the durability of the electronic component. Further, since the sputtered metal layer is formed on the end face of the core member, it is possible to reduce the electrical resistance between the core member and the conductive resin layer and to improve the electrical characteristics of the electronic component. Furthermore, since the bondability between the sputtered metal layer and the conductive resin layer is excellent, it is possible to improve the bonding strength of the external electrode.

Further, according to the invention, the sputtered metal layer may include a first metal layer that is selected from Ti, Ni, Cr, Al, and alloys thereof; and a second metal layer that is selected from Cu, Au, Ag, Pt, and Sn.

According to this configuration, it is possible to reduce the contact resistance between the conductive resin layer and the sputtered metal layer by improving adhesion to glass.

Further, according to the invention, the sputtered metal layer is formed so as to cover the through hole.

According to this configuration, since the contact area between the sputtered metal layer and the conductive resin layer is increased, it is possible to further increase the bonding strength of the external electrode.

Furthermore, according to the invention, the external electrode includes an insulating resin layer that is formed between the substrate and the conductive resin layer and covers a region except the through hole.

According to this configuration, since the external electrode further includes the insulating resin layer, it is possible to improve a cushioning property against impact and vibration. Accordingly, it is possible to improve the durability of the electronic component.

Moreover, according to the invention, the electronic element is a crystal oscillating piece. According to this, it is possible to provide a crystal oscillator that has excellent durability and excellent electrical characteristics.

According to the invention, it is possible to reduce the electrical resistance between the conductive resin and the core member used in the through electrode and there is no need to concern about the deterioration of the bondability between the lead-free low melting-point glass and the conductive resin. Accordingly, it is possible to provide an electronic component that has excellent durabilities and improved electrical characteristics, and a method of manufacturing the electronic component.

### BRIEF DESCRIPTION OF THE DRAWINGS

FIG. 1 is a view showing a state where an electronic component according to the invention is mounted on a circuit board.

FIG. 2 is a view showing an external electrode of the electronic component according to the invention.

FIG. 3 is a view showing an external electrode of an electronic component according to the invention.

FIG. 4 is a view showing an external electrode of an electronic component according to the invention.

### DETAILED DESCRIPTION OF THE PREFERRED EMBODIMENTS

A first embodiment to which the invention can be applied will be described.

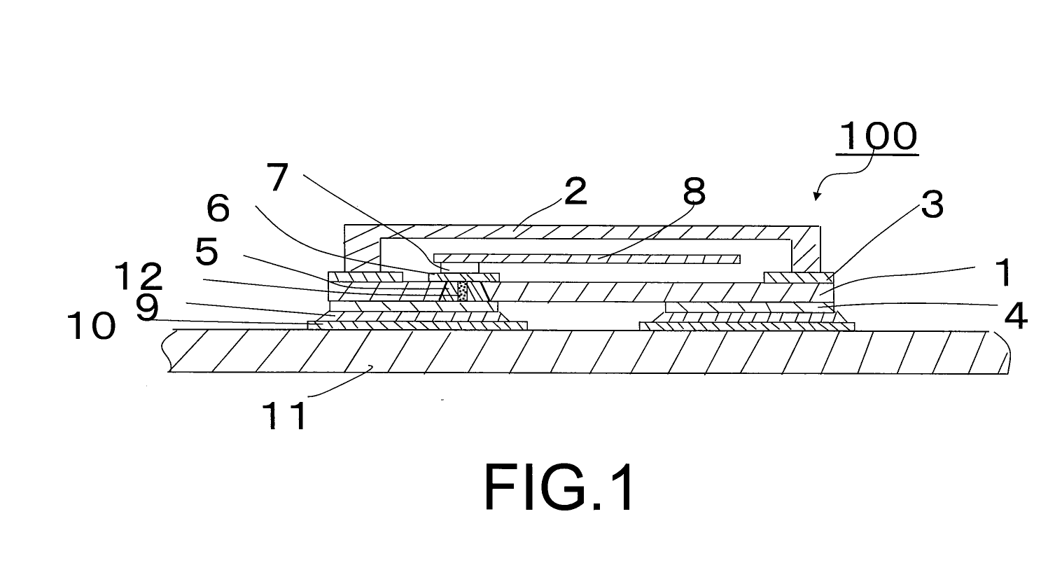

FIG. 1 is a view showing a state where a crystal oscillator 100 as an electronic component according to this embodiment is mounted on a circuit board 11.

In this embodiment, the crystal oscillator 100 is used as an electronic component. However, an electronic component to which the invention can be applied is not limited to the crystal oscillator 100, and has only to include a glass package. The crystal oscillator 100 includes a substrate 1 that is made of glass, an internal electrode 6 that is formed on one surface of the substrate 1, an external electrode 4 that is formed on the other surface of the substrate, a through hole that passes through the substrate 1, a through electrode that is disposed in the through hole and electrically connects the internal electrode 6 to the external electrode 4, and a crystal oscillating piece 8 that is provided on one side of the substrate 1 and electrically connected to the internal electrode 6.

A hollow structure is formed between the substrate 1 and a lid 2, and the crystal oscillating piece 8 is received in the hollow structure. Further, each of the peripheries of the substrate 1 and the lid 2 is bonded to bonding portions 3. Further, the crystal oscillating piece 8 is connected to the internal electrode 6 through a connecting portion 7.

The external electrode 4 is soldered to lands 10, which are formed on the circuit board 11, by solder 9, so that the crystal oscillator 100 is mounted on the electronic circuit board 11. Pb-free solder may be used as the solder 9.

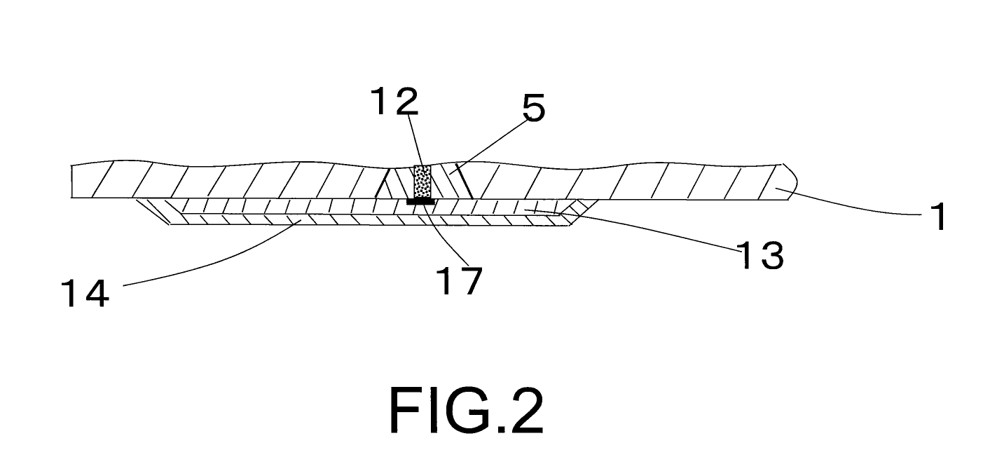

The configuration of the external electrode 4 of the crystal oscillator 100 will be described with reference to FIG. 2. FIG. 2 is a view showing the external electrode 4 of the crystal oscillator 100.

A through hole having a substantially trapezoidal cross-section is formed at the substrate 1, and a metal core member 12, which is a through electrode, is provided in the through hole. The thickness of the substrate 1 is in the range of 0.2 to 0.4 mm. Further, a space between the core member 12 and the through hole is filled with lead-free low melting-point glass 5, so that the through hole is sealed. Meanwhile, the lid 2 is made of ceramic, silicon, other inorganic single crystals, glass, metal, an alloy, or the like.

Solder, which contains gold and tin, is used as a bonding material 7 for the connection between the crystal oscillating piece 8 and the internal electrode 6. Further, high-temperature solder may be used other than this solder, and the crystal oscillating piece 8 and the internal electrode 6 may be bonded to each other by ultrasonic bonding using an Au bump.

It is particularly preferable that the glass used for the substrate 1 be soda glass. Soda glass is also called soda-lime glass, and contains silica (SiO2), calcium carbonate, and sodium carbonate as main materials, and is manufactured by a float method. A thin glass plate of soda glass, which is manufactured by a float method, can be manufactured at a lower cost than plates that are manufactured by other methods.

Further, if glass is used for the substrate 1, the hollow structure formed on the substrate 1 may have a large space. Accordingly, there is also an advantage that the bonding between the internal electrode 6 and an electronic element such as the crystal oscillating piece 8 and the bonding between the lid 2 and the substrate 1 can be collectively performed by using the space.

Furthermore, the crystal oscillator 100, which uses glass as the substrate 1, has a great advantage that a frequency can be adjusted by laser outside a package after the crystal oscillating piece 8 is airtightly sealed in the package.

Further, the coefficient of thermal expansion of the substrate 1 using glass is close to that of the crystal oscillating piece 8. For this reason, there is no concern that the substrate 1 and the crystal oscillating piece 8 are deformed by applying stresses to each other when their thermal expansions occur.

However, glass is more brittle than ceramics, alumina, plastics, or the like, and has a problem that it is difficult to relax stress when a vibration or impact is applied. Accordingly, in order to solve this problem, a conductive resin layer 13 is provided on the external electrode 4 in this embodiment so that stress is relaxed and the durability of the crystal oscillator 100 is improved. This will be described in detail below.

The core member 12 is formed of a Dumet wire or a Ni alloy, such as a Fe—Ni alloy, a kovar alloy (Fe—Ni—Co alloy), or a Fe—Ni—Cr alloy, which has excellent adhesion to glass and has a low coefficient of expansion, close to the coefficient of thermal expansion of glass.

Further, glass, which is obtained by removing lead from borosilicate glass or the like and making the melting point low, is mainly used as the lead-free low melting-point glass 5. Here, a low melting-point means a melting point of about 700° C. or less. Furthermore, a filler may be added to the lead-free low melting-point glass 5 for the adjustment of a coefficient of thermal expansion and the improvement of the strength.

Here, since the lead-free low melting-point glass 5 is apt to be in an unstable state as described above, there is a concern that the bonding strength of the external electrode 4 is reduced at the contact portion between the lead-free low melting-point glass 5 and the conductive resin layer 13 when the conductive resin layer 13 is used for the external electrode 4. Moreover, there is a problem in that electrical resistance between the core member 12 and the external electrode 4 is greatly increased when the core member 12 is directly bonded to the conductive resin of the external electrode 4.

Accordingly, in this embodiment, the durability of the crystal oscillator 100 is improved by the formation of the conductive resin layer 13, a sputtered metal layer 17 is formed on the end face of the core member 12, and the core member 12 and the conductive resin layer 13 are bonded to each other by the sputtered metal layer 17. Meanwhile, the conductive resin layer 13 covers the sputtered metal layer 17 and the peripheral portion of the through hole.

In this configuration, it is possible to make the electrical resistance between the conductive resin layer 13 and the sputtered metal layer 17, which is formed on the end face of the core member 12, greatly lower than the electrical resistance therebetween when the sputtered metal layer 17 is not formed. That is, it is possible to improve the electrical characteristics of the crystal oscillator 100. Further, since the sputtered metal layer 17 and the conductive resin layer 13 are strongly bonded to each other, there is no concern about the reduction of the bonding strength at the contact portion between the lead-free low melting-point glass 5 and the conductive resin layer 13 as described above. Accordingly, it is possible to improve the electrical characteristics of the crystal oscillator 100 by forming the sputtered metal layer 17 while improving the durability of the crystal oscillator 100 by forming the conductive resin layer 13.

Meanwhile, the sputtered metal layer 17 of this embodiment is made of Al or an Al alloy. However, the sputtered metal layer 17 may have a two-layer structure that is formed of one (first metal layer) of Ti, Ni, Cr, Al, and alloys thereof and one (second metal layer) of Cu, Au, Ag, Pt, and Sn. Ti, Ni, Cr, and Al have an advantage that the adhesion to glass is excellent. Further, Cu, Au, Ag, Pt, and Sn have an advantage that a contact resistance between the conductive resin layer 13 and Cu, Au, Ag, Pt, and Sn is low. However, since the adhesion between glass and Cu, Au, Ag, Pt, and Sn is low, Ti, Ni, Cr, and Al need to be used as the foundation.

Furthermore, the sputtered metal layer 17 may have a three-layer structure where Cr, Ni, and Au are laminated in this order. The bondability of this three-layer structure can be further improved as compared to the bondability of the two-layer structure or the one-layer structure. In this case, Ni between Cr and Au functions as a barrier layer between the conductive resin layer 13 and the lead-free low melting-point glass 5.

Meanwhile, these metals do not need to be used substantially in a pure state, and may be used in the form of an alloy such as Al—Si or Ni—Cr.

An insulating resin mixed with a conductive filler may be used for the conductive resin layer 13. Here, as the insulating resin, ones obtained by adding a filler such as an inorganic material to, for example, an epoxy resin, a phenol resin, a polyimide resin, a polyamide-imide resin, a polyallylether resin, a cyanate resin, or modified resins thereof, as a main ingredient, if needed, may be used. Further, Ag, Ag alloy, Cu coated with Ag, Cu, a mixed filler of Ag and Cu, a mixed filler of Ag and Ni, and the like may be used as the conductive filler.

Further, in this embodiment, the conductive resin layer 13 is covered with a metal electrode layer 14 as shown in FIG. 2. The metal electrode layer 14 is made of Cu or Ni. When the metal electrode layer 14 is made of Cu, the thickness of the metal electrode layer 14 may be equal to or larger than 5 μm. When Ni is used for the metal electrode layer 14, the thickness of the metal electrode layer 14 may be equal to or larger than 1 μm. Meanwhile, it is appropriate that the thickness of the entire conductive resin layer 13 is in the range of 10 to 60 μm. Since the surface of the conductive resin layer 13 is covered with the metal electrode layer 14 as described above, the bondability between the metal electrode layer 14 and the solder 9 is excellent, and it is possible to preferably mount the crystal oscillator 100 on the circuit board 11 by the solder 9. Meanwhile, the surface of the metal electrode layer 14 may be further covered with a passivation layer that is formed of one layer of Sn, Au, Ag, Pt, or the like or two layers of Pd and Au. The corrosion resistance of the metal electrode layer 14 is improved through the formation of the passivation layer.

The metal electrode layer 14 is formed on the conductive resin layer 13 by plating. The plating may be electrolytic plating or electroless plating, but the electroless plating is preferable. When the metal electrode layer 14 is made of Ni, Ni—P based electroless plating and Ni—B based electroless plating may be used as the electroless plating. Meanwhile, Ni—P or the like, which is formed by electroless plating, can further reduce the electrical resistance between the conductive resin layer 13 and the external electrode. Further, since electroless Ni—P has excellent corrosion resistance, Au formed on the passivation layer may be made very thin.

A method of manufacturing the crystal oscillator 100 according to this embodiment will be described below.

First, a process for disposing the metal core member 12 in the through hole, which is formed at the substrate 1 made of glass, and sealing the core member 12 with the lead-free low melting-point glass 5 is performed.

Next, a process for forming the internal electrode 6 on the substrate 1 is performed. The internal electrode 6 can be formed by plating, sputtering, or the like.

Next, a process for disposing the crystal oscillating piece 8 on the internal electrode 6 is performed. An organic conductive adhesive is used at the connecting portion 7 between the crystal oscillating piece 8 and the internal electrode 6. Alternatively, high-temperature solder may be used or ultrasonic bonding may be performed using an Au bump. After that, the substrate 1 and the lid 2 are bonded to each other, so that a glass package is formed.

If the lid 2 is made of glass in the process for bonding the lid 2 to the substrate 1, anodic bonding or laser bonding for directly melting glass may be applied to the bonding between the lid 2 and the substrate 1. Further, the lid 2 and the substrate 1 may be bonded to each other with a low melting-point glass or the like interposed therebetween. Furthermore, laser bonding may be performed while a laser light absorbing material is interposed between the lid 2 and the substrate 1. Moreover, high-temperature solder or an organic resin may be used for the bonding between the lid 2 and the substrate 1.

Meanwhile, the hollow structure is formed in the glass package, which is obtained by forming a recess at the lid 2 through press molding. Meanwhile, the hollow structure may be formed by forming a recess at the lid 2 through etching, or through sandblasting. Further, it may be possible to form a recess by forming side walls at the lid 2 by a thick film method.

When the bonding between the lid 2 and the substrate 1 is completed, a process for forming the external electrode 4 on the outer surface of the substrate 1 is performed. In this process, first, the sputtered metal layer 17 is formed on the end face of the core member 12, which faces the external electrode 4, by sputtering. Next, the sputtered metal layer 17 is covered with the conductive resin layer 13. Finally, the conductive resin layer 13 is covered with the metal electrode layer 14. Accordingly, the external electrode 4 is formed.

The crystal oscillator 100 shown in FIG. 1 is formed as described above. After that, the external electrode 4 is soldered to the lands 10, which are formed on the circuit board 11, by the solder 9, so that the crystal oscillator 100 can be mounted on the circuit board 11.

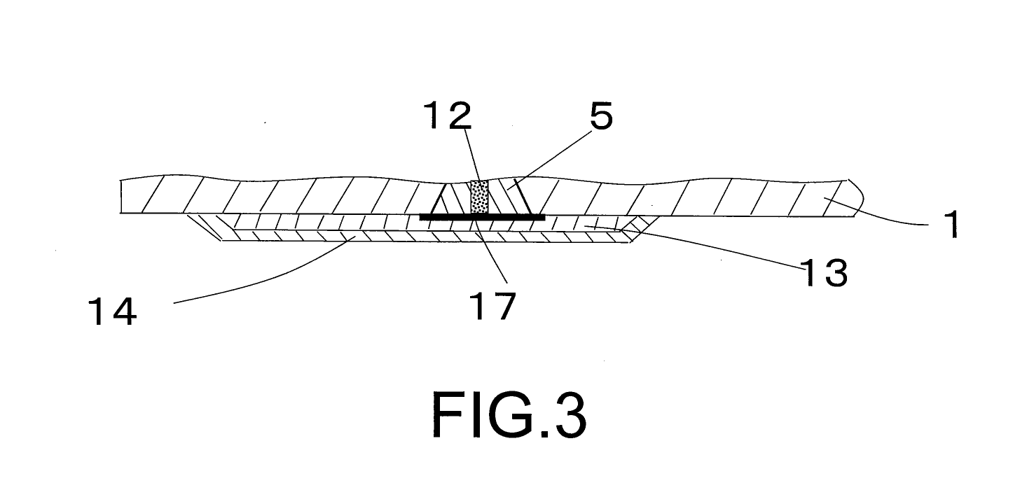

Next, a second embodiment of the invention will be described with reference to FIG. 3. Meanwhile, since the second embodiment is different from the first embodiment only in terms of the configuration of the external electrode 4, the description of the same parts as the parts of the first embodiment will be omitted.

In this embodiment, the sputtered metal layer 17 formed on the end face of the core member 12 is widely formed so as to cover at least the entire lead-free low melting-point glass 5. As described above, the bondability between the sputtered metal layer 17 and the conductive resin layer 13 is excellent. According to this configuration, it is possible to improve the bondability between the external electrode 4 and the lead-free low melting-point glass 5.

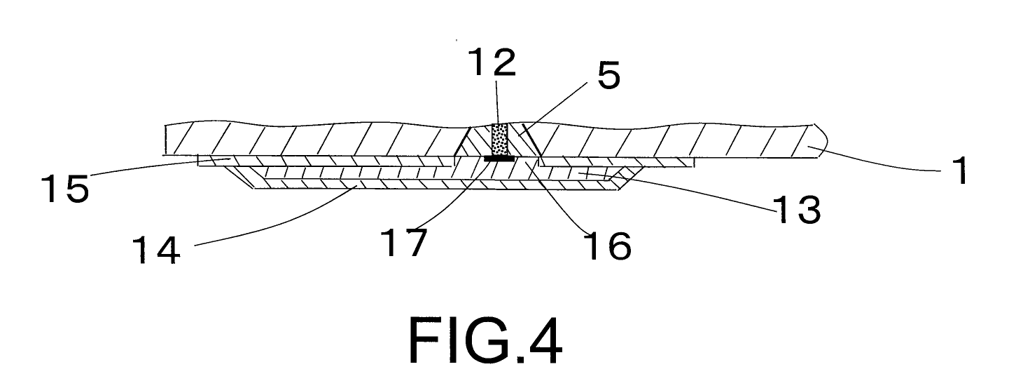

Next, a third embodiment of the invention will be described with reference to FIG. 4. Meanwhile, the description of the same parts as the parts of the first and second embodiment will be omitted even in this embodiment.

In the third embodiment, an insulating resin layer 15 is formed between the conductive resin layer 13 and the substrate 1. That is, the external electrode 4 of the third embodiment includes an insulating resin layer 15, which covers the outer surface of the substrate 1 at a region between the open end of the through hole and the peripheral portion of the through hole, that is, a region except the through hole.

An opening portion 16 is formed at the insulating resin layer 15, and the opening portion 16 is aligned with the through hole of the substrate 1. Meanwhile, the same sputtered metal layer 17 as the sputtered metal layer of the first or second embodiment is formed on the end face of the core member 12 that is disposed in the through hole.

The insulating resin layer 15 is made of, for example, an epoxy resin, a phenol resin, a polyimide resin, a polyamide-imide resin, a polyallylether resin, a cyanate resin, or resins that are obtained by adding a filler such as an inorganic material to these resins. The insulating resin layer 15 has flexibility and a stress relaxing property. For this reason, the insulating resin layer 15 has an effect of relaxing the stress of the glass package when a vibration or impact is applied. That is, according to this embodiment, it is possible to further improve the durability of the glass package by forming not only the conductive resin layer 13 but also the insulating resin layer 15.

Meanwhile, a metal electrode cannot be formed on the insulating resin layer 15 by plating. Accordingly, in order to secure the conductivity of the external electrode 4, it is necessary to make the conductive resin layer 13 further come into close contact with the sputtered metal layer 17 while forming the sputtered metal layer 17 on the end face of the core member 12. Meanwhile, the total thickness of the two layers, that is, the insulating resin layer 15 and the conductive resin layer 13 is appropriately in the range of 20 to 80 μm.

As described above, according to this embodiment, the two layers, that is, the conductive resin layer 13 and the insulating resin layer 15 are formed, and thus this embodiment is advantageous in terms of relaxing stress and improving the bonding strength to the glass as compared to the case where a single conductive resin layer 13 is formed. Moreover, since the insulating resin layer 15 functions as a heat insulation material, it is possible to provide the crystal oscillator 100 whose characteristics are not likely changed even under a high temperature.

What is claimed is:

1. An electronic component comprising:
a substrate that is made of glass;
a lid that is bonded to the substrate;
an internal electrode that is formed on one surface of the substrate;
an external electrode that is formed on the other surface of the substrate;
a through electrode that is disposed in a through hole passing through the substrate and electrically connects the internal electrode to the external electrode; and
an electronic element that is provided on one side of the substrate and electrically connected to the internal electrode,
wherein the through electrode is formed of a core member that is disposed in the through hole and made of a metal, and lead-free low melting-point glass that seals a space between the core member and the through hole, and a sputtered metal layer is formed on the end face of the core member, which faces the external electrode, by sputtering,
the external electrode includes a conductive resin layer and a metal electrode layer that covers the outer side of the conductive resin layer, and
the sputtered metal layer and the conductive resin layer are bonded to each other, so that the electrical connection among the internal electrode, the core member, and the external electrode is secured.

2. The electronic component according to claim 1,
wherein the sputtered metal layer includes a first metal layer that is selected from Ti, Ni, Cr, Al, and alloys thereof, and a second metal layer that is selected from Cu, Au, Ag, Pt, and Sn.

3. The electronic component according to claim 1,
wherein the sputtered metal layer is formed so as to cover the through hole.

4. The electronic component according to claim 1,
wherein the external electrode includes an insulating resin layer that is formed between the substrate and the conductive resin layer and covers a region except the through hole.

5. The electronic component according to claim 1,
wherein the electronic element is a crystal oscillating piece.
